(19) United States
(12) Patent Application Publication
(10) Pub. No.: US 2004/0025932 A1
(43) Pub. Date: Feb. 12, 2004

(54) Variegated, high efficiency solar cell and method for making same

(76) Inventor: John Husher, Los Altos, CA (US)

Correspondence Address: DORSEY & WHITNEY LLP, Suite 3400, Four Embarcadero Center, San Francisco, CA, 94111-4187, US

(21) Appl. No.: 10/218,687

(22) Filed: Aug. 12, 2002

(51) Int. Cl. H01L 31/00

(52) U.S. Cl. 136/256; 438/98

(57) ABSTRACT

A solar cell is provided comprising a substrate having a light-receiving first surface and a variegated second surface, the second surface having at least first and second recesses. The substrate is doped within the first recess to provide a p-type region, and within the second recess to provide an n-type region. At least one conductive material is disposed in each of the first and second recesses, permitting electrical connections to the p-type and n-type regions. In a first embodiment, using selective deposition, tungsten fills the slots and slots may have a depth of up to 60 microns. In a second embodiment, a sputtering technique is used to deposit metal in the slots, and slots may have a depth of up to about 10 microns.

### FIELD OF THE INVENTION

The present invention relates generally to solar cells and more particularly to a high efficiency solar cell.

### BACKGROUND

Solar cells convert incident light to electrical energy, and briefly operate as follows. A solar cell generally includes a semiconductor substrate material having first and second surfaces. Light falling on a first light-receiving surface of a semiconductor substrate generates hole-electron pairs as the incoming energy is absorbed by the material. The energy absorbing properties of this first light-receiving surface may be enhanced by texturing the surface or providing an anti-reflective coating. Further, the energy incident on the surface may be increased by focusing the light with lens(es).

On the opposite substrate surface, one or more PN junctions are provided (See FIG. 1). Briefly, a PN junction is a p-type region of semiconductor material adjacent to an n-type region of semiconductor material.

Holes and electrons generated by incoming light diffuse in the substrate material to an extent determined by their carrier diffusion length. If the pairs reach the depletion region of the PN junctions they flow in the electric field and contribute to electrical current generated by the solar cell in response to the incoming light.

There are a variety of factors which effect the efficiency of a solar cell including losses in the metal carrying the current, hole-electron pair recombination in the body of the silicon, and the operating temperature of the cell. Solar cells currently operate with efficiencies of about 10 to 20 percent and there is a need to provide a highly efficient solar cell.

Accordingly, it is an object of this invention to provide a highly efficient solar cell.

It is a further object of the present invention to decrease efficiency losses in the metal.

It is another object of the present invention to maximize the number of electrons and holes that reach the depletion regions and contribute to the solar cell current.

It is a further object of the present invention to provide improved heat management in a solar cell.

### SUMMARY OF THE INVENTION

A solar cell is provided comprising a substrate having a light-receiving first surface and a variegated second surface, the second surface having at least first and second recesses. The substrate is doped within the first recess to provide a p-type region, and within the second recess to provide an n-type region. At least one conductive material is disposed in each of the first and second recesses, permitting electrical connections to the p-type and n-type regions. In a first embodiment, the recesses may be relatively deep and the conductive material is preferably tungsten. In another embodiment, the recesses may be less deep and the conductive material comprises aluminum, aluminum/silicon, or aluminum/silicon/copper.

Methods for making a solar cell are also provided. These methods preferably include the selective chemical vapor deposition of tungsten into the recesses of the variegated surface of the substrate with the-deep recesses, or slots. In another embodiment, shallow recesses are formed and metal is sputtered into the variegated surface of the substrate.

### BRIEF DESCRIPTION OF THE DRAWINGS

The accompanying drawings, which are somewhat schematic in some instances and are incorporated in and form a part of this specification, illustrate one embodiment of the invention and, together with the description, serve to explain the principles of the invention.

FIG. 1 is a cross-sectional view of a solar cell according to the prior art.

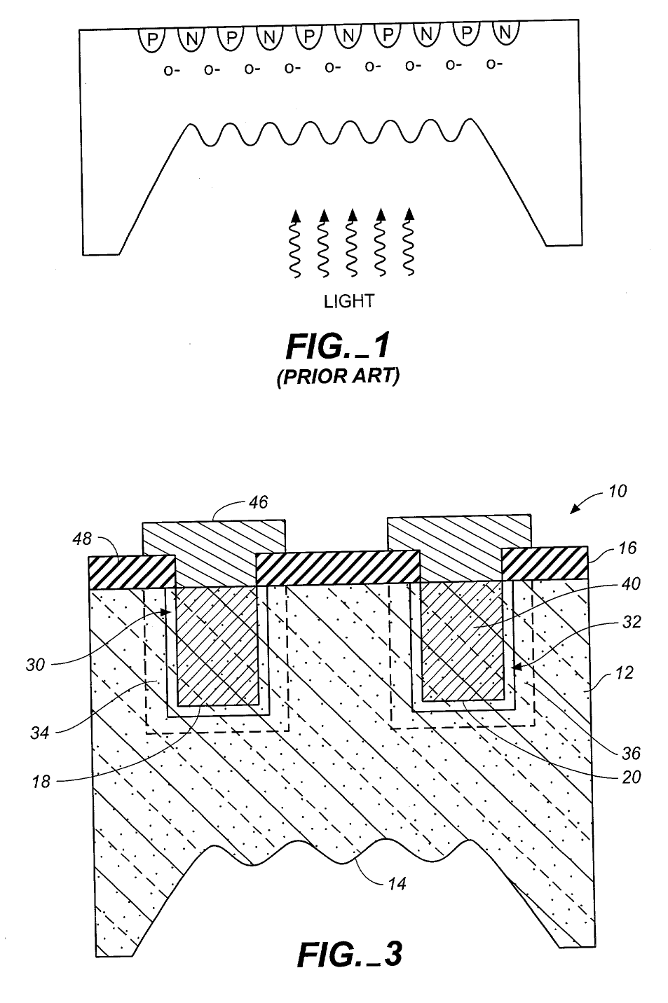

FIG. 2 is a plan view of a solar cell according to an embodiment of the present invention.

FIG. 3 is a cross-sectional view of the solar cell of FIG. 2, taken along line 2-2 of the solar cell of FIG. 2.

FIGS. 4A-G are a series of cross-sectional views of the solar cell of FIG. 2 at various stages during its fabrication.

FIG. 5 depicts a cross-sectional view of one recess of a solar cell according to an embodiment of the present invention having shallower slots during a metallization

FIG. 6 depicts a cross-sectional view of one recess of a solar cell according to an embodiment of the present invention having shallower slots during a metallization.

FIG. 7 depicts a cross-sectional view of one recess of a solar cell according to an embodiment of the present invention having shallower slots during a metallization

### DESCRIPTION OF THE INVENTION

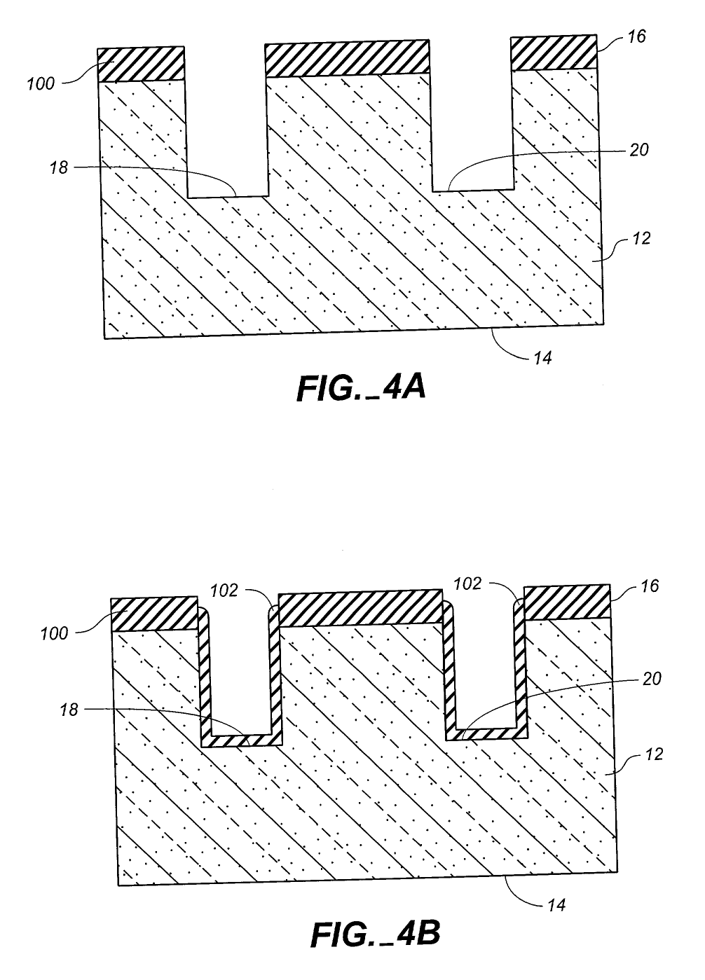

A solar cell of the present invention is generally represented by solar cell 10 comprising substrate 12 with first surface 14 opposite second surface 16 (see FIG. 3). First surface 14 is a light receiving surface and may be thinned, textured, and/or may be coated with an anti-reflective coating to reduce the reflection of incoming available light. In a preferred embodiment, substrate 12 is made of high resistivity, long lifetime, n-type silicon, that is silicon generally having a concentration of n-type dopants between 10¹² and 10¹⁴/cm³. It will be understood to those in the art that high-resistivity, long lifetime, p-type silicon may also be used as a substrate for a solar cell according to the present invention, with minor variations on the specific procedures that follow. Similarly, other substrates commonly used for solar cells may be used.

According to the present invention, solar cell 10 preferably has a variegated second surface 16 that includes recesses, or slots, such as first recess (slot) 18 and second recess (slot) 20. The recesses, or slots, may define substantially any cross-sectional shape, including square, rectangular, curved, or the like. In a preferred embodiment, recesses 18 and 20 are slots having a rectangular cross-section, extending parallel to each other. For convenience, ‘recesses’ and ‘slots’ may be used interchangeably throughout this discussion, however, it is to be understood that the inventive solar cell is not limited to having slots on one surface. Rather, the surface is simply variegated in some manner to create a greater depletion region area per square surface exposed to light. Additionally, all recesses need not have the same cross-sectional shape or dimension, although solar cell 10 is shown with two identical slots. However, in preferred embodiments all slots have the same depth to simplify the processing required to form the slots. There may be any number of recesses per solar cell, depending on the size of the solar cell and the dimensions used for the slot width and spacing between slots.

The spacing between recesses is determined by the intended depth of the doped regions, plus the depletion region length expected from the doped regions into the starting material. The recesses are defined far enough apart, e.g. about 30 μm to about 50 μm apart, to prevent adjacent depletion regions from making contact. In some embodiments, slots have a width of between 5 μm and 10 μm, and a depth between 20 and 60 microns, and for these embodiments an exemplary width of 6 microns and a depth of 25 microns will be discussed. In other embodiments, shallower recesses are generally formed, for which embodiments an exemplary width of 6 microns and a depth of 6 microns may be used. The slot dimensions are chosen based on what can be achieved with the particular technique used to create the slots, as well as the conformity of the metallization procedure.

At least one recess, such as recess 18, is defined by a region having opposite doping to that of the substrate. Accordingly, first recess 18 is defined by p-type region 30, where substrate 12 is n-type material, e.g. silicon. P-type region 30 generally has a concentration of p-type dopants between about 10¹⁸/cm³ to about 10¹⁹/cm³. Advantageously but optionally, second recess 20 is defined by highly doped n-type region 32, doped with a higher concentration than the remainder of the substrate, to facilitate low contact resistance to a subsequent conductive material deposition. Highly doped n-type region 32 may have a concentration of n-type dopants ranging from about 5×10¹⁹/cm³ to about 5×10²⁰/cm³. Alternatively, recess (slot) 20 is simply defined by the n-type substrate and no further doped region is necessary.

P-type region 30 is preferably doped with boron, while n-type substrate 12 or highly doped n-type region 32 is preferably doped with phosphorous. The choice of particular dopant species is dependent on the substrate material and doping method. In another embodiment, n-type region 32 is doped with arsenic.

Depletion region 34 is created in substrate 12 as a result of the presence of p-type region 30. Additionally, depletion region 36 may be created, due to n-type region 32, but will be relatively insignificant in depletion length since it is an N+ dopant in N− type material (high resistivity, long lifetime, starting substrate material).

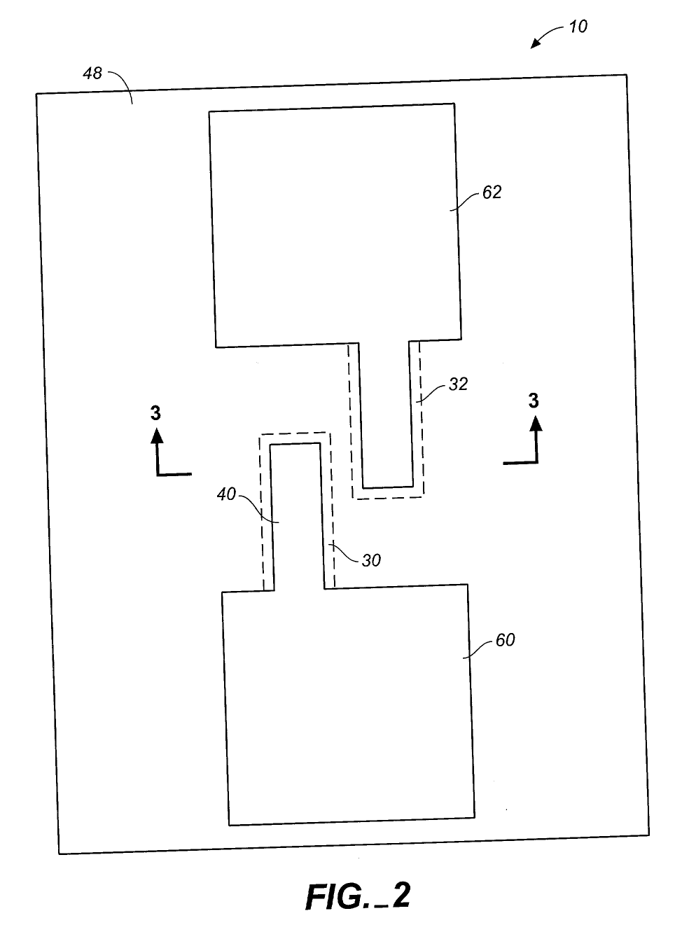

At least one conductive material, such as conductive material 40, is disposed in recesses (slots) 18 and 20 to permit electrical connections to the p-type and n-type regions. The conductive material preferably contacts the substrate continuously within the recess, that is the bottom and sides of slot 18, are in continuous contact with the conductive material. The conductive material is preferably tungsten in embodiments comprising deep slots, for reasons described below. Conductive material (tungsten) 40 is shown in FIG. 2 disposed in recess (slot) 18 and filling the recess. In an alternative embodiment, conductive material 40 is deposited such that it lines the recess, permitting a gap to exist within the recess.

Alternatively, an additional conductive material 46 may be provided that is electrically connected with conductive material 40. This additional conductive material may be the same material as conductive material 40, preferably tungsten, or a different material, such as aluminum, aluminum/silicon, aluminum/silicon/copper or copper.

Insulating material 48, preferably silicon dioxide, may be provided on surface 16 of solar cell 10 in regions other than the recesses, that is, in the field.

In a preferred embodiment, recesses 18 and 20 are placed such that conductive material 40 will electrically connect to bonding pad 60 (see FIG. 2). In this manner, no additional contact opening or metal patterning is required. Generally, two bond pads, such as bond pad 60 and 62 are provided, one pad to connect with recesses defined by p-type regions, such as recess 18, and one pad to connect with second recesses defined by n-type regions, such as recess 20. More bond pads may be provided, depending on the size of the solar cell and the relative distance to the bonding pads. In embodiments described above where additional conductive material 46 is placed above conductive material 40, the additional conductive material may be patterned. The bond pads may be arranged in substantially any configuration relative to the first and second recesses.

Although only two recesses are shown in FIG. 3, it is to be understood that more recesses may be provided, and therefore, a plurality of p-type recesses may connect with bonding pad 60, and a plurality of n-type recesses with bonding pad 62. Bonding pads 60 and 62 are sized and placed to be the output terminals of the solar cell, as such they may be substantially any shape, with square being preferred. Bonding pads 60 and 62 are generally composed of aluminum or copper. A device to collect current from the solar cell may interface with bond pads 60 and 62.

As is known in the art, a variety of other structures may be associated with solar cell 10. For example, lenses may be operatively associated with solar cell 10 to focus incoming light on light-receiving surface 14, to enhance solar cell output current. Further, dielectrics and other anti-reflective coatings may be provided on surface 14, to enhance solar cell output current. These and other features that may be added to solar cell 10 are known and commonly used.

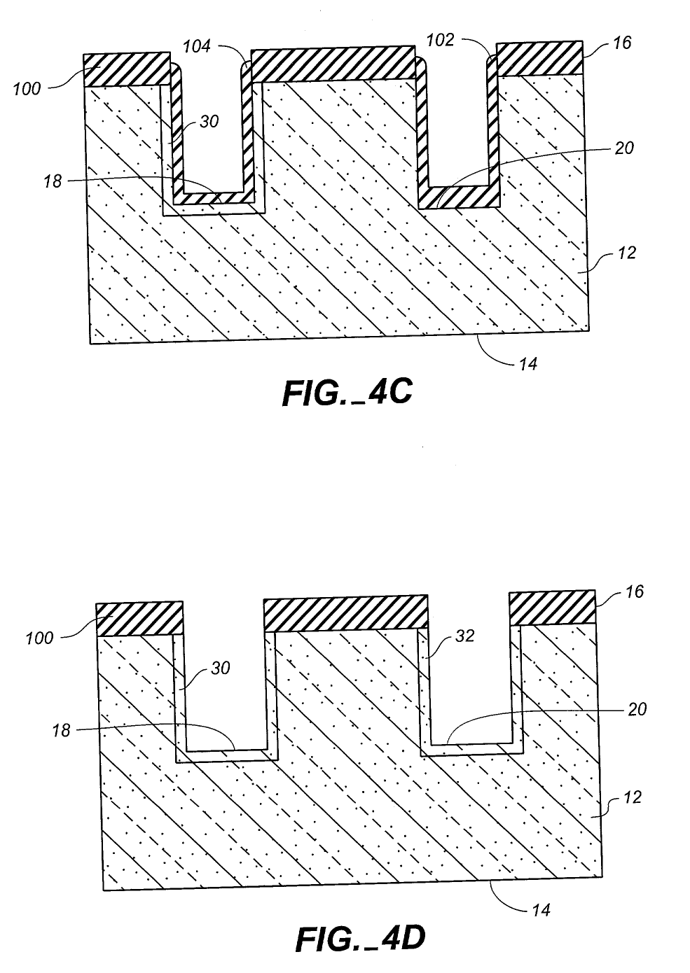

The present invention further provides methods for the fabrication of a solar cell, such as solar cell 10. Recess 18 and 20 may be formed in substrate 12 using any of a variety of methods known in the art, preferably photolithography to define masking layer 100 and dry (plasma anisotropic) etching to define 18 and 20 as shown in FIG. 4A. However, depending on the substrate material and geometry of the recesses, wet etching may also be employed. Masking material 100, patterned to allow the etchant access to the recesses, is preferably silicon dioxide and can be formed simply by oxidizing silicon substrate 12. The depth of the slots is generally between 20 μm and 60 μm for embodiments comprising deep slots, and 5 μm to 10 μm for embodiments comprising shallow slots. In this example, the slots are 6 μm wide.

After recesses (slots) 18 and 20 are formed in substrate surface 12, a masking layer 102 is provided to cover the recesses as shown in FIG. 4B. In a preferred embodiment, the substrate is oxidized to provide masking layer 102 along the surface of the recesses. In other embodiments, a masking layer may be deposited on the surface having recesses, for example using chemical vapor deposition. Previous masking layer 100 may but need not be removed prior to the formation of masking layer 102. Masking layer 102 is then removed above first recess 18, in a lithographic process. It is to be understood that, in embodiments having a plurality of first recesses, masking layer 102 may be removed from all first recesses in this step.

Dopant species are introduced and diffused into first recess 18, forming p-type region 30 (see FIG. 4C). The time, temperature, and other variables involved in the diffusion process depend on the substrate material, dopant species, and desired depth of p-type region 30 and are known in the art. The diffusion is preferably performed in an oxidizing atmosphere resulting in first recess 18 defined by p-type region 30 having thin oxide 104 (see FIG. 4C) lining recess 18.

Thin oxide 104 is usually between 100 nm and 200 nm in thickness, although other thickness sufficient to serve as a masking layer during the next step are acceptable. Next, masking layer 102 above second recess 20 is removed in a photomasking step, to allow dopant species to be introduced and diffused into second recess 20. The photoresist material used for masking and etching the oxide may be left on the surface to form a barrier to an N-type implant that is used to implant slot 20 and form highly doped n-type region 32. This junction need not be as deep as the P junction, since it serves as a low resistance contact to the substrate. It is noted that in this embodiment, the depth of the highly doped p-type regions will be determined by the time and temperature of both the first and second diffusion steps. These time and temperatures are chosen to provide the junction depth of the p-type regions and to provide a high surface concentration for the n-type regions to ensure low contact resistance to a subsequent metal deposition.

Any remaining masking material is removed from the recess regions, leaving masking material 100, usually silicon dioxide, in the field (see FIG. 4D). Although the insulating material left in the field is depicted in FIG. 4D as masking material 100, in other embodiments, the insulating material in the field (corresponding to layer 48 in FIGS. 2 and 3) may not be masking material 100. That is, at any of a variety of times during the fabrication of solar cell 10, masking material 100 may be removed and insulating material 48 deposited. If desired, the photoresist material may also be left in place to serve as added protection against implants.

Conductive material is then deposited in the recesses (see FIG. 4E). Preferably, this step utilizes the selective CVD of tungsten, involving exposing the silicon substrate of the recessed regions to WF6 gas. The CVD is selective in that the initial thickness of tungsten is due to a reaction between the WF6 gas and the silicon substrate itself. This results in thin tungsten layer 110 in areas of the solar cell where the surface is silicon, that is the recesses (slots), but not in the field, areas where the surface is covered in the non-silicon masking layer 48 (see FIG. 4E). This initial reaction is self-limiting, forming a thickness of approximately several hundred Angstroms. Selective CVD of tungsten is further described in “Silicon Processing for the VLSI Era” by S. Wolf and R. N. Tauber, 1986, by Lattice Press, incorporated herein by reference.

To supplement the initial, self-limited thickness of tungsten 110, the tungsten is thickened by the introduction of hydrogen gas that reacts with the WF6 to thicken the tungsten material that is started in the recesses. tungsten 114 is preferably deposited such that it fills the recesses completely (see FIG. 4F). It is noted that tungsten 114 adds to initial starting layer 110, shown in FIG. 4E, but for simplicity starting layer 110 is not shown in FIG. 4F. In other embodiments, where tungsten is not used as the conductive material (as described for shallow slot embodiments), a gap may be left within the recesses.

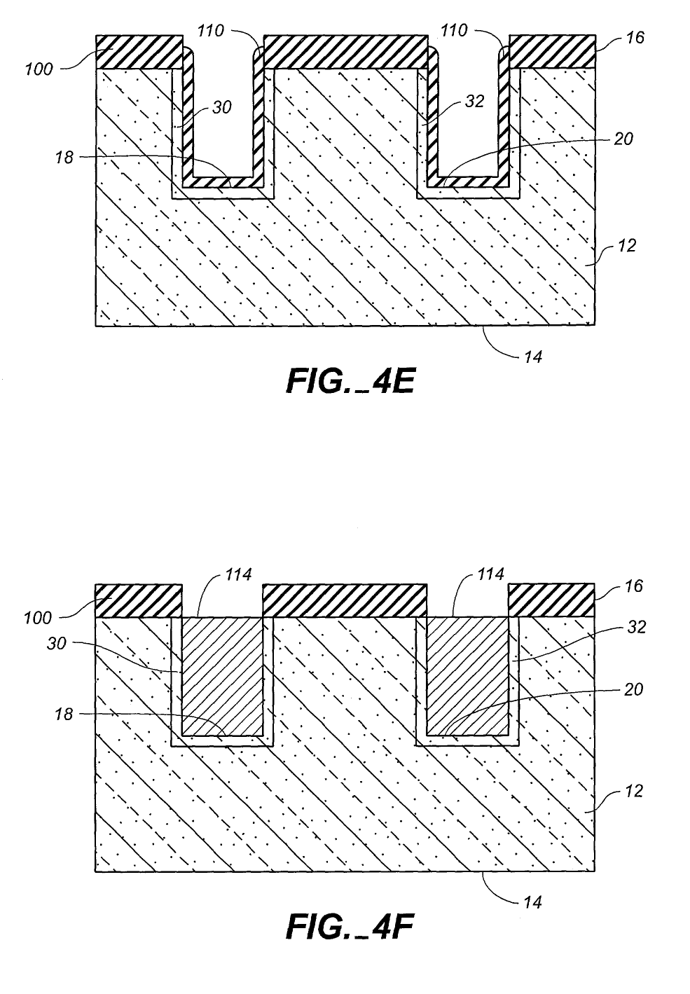

Using tungsten for this metal layer advantageously fills the deep and narrow slots indicated by chemical reaction with the silicon at the bottom of the slots. Further, additional thickness results by chemical reaction of plating tungsten onto the seed tungsten that has been grown. The slot then fills-up from the bottom and sides to be completely filled. This method allows relatively deep slots to be filled, e.g. filled slots may be even deeper than the 60 μm mentioned above. Deeper slots can make the collection of hole-electron pairs even more efficient as described below.

Where a CVD system is not available for creating the tungsten to fill the slots, shallower slots can be provided. A sputter system is used to deposit the conductive material in such shallower slots. Generally, as used herein, shallow slots, or recesses, refer to a depth of about 5 microns to about 10 microns and 5 microns to greater than 5 microns in width. The size limitation of shallow slots filled with conductive material by a sputter system will depend on the ability of the sputter system to adequately line the recesses with conductive material. Further, shallow slots may be filled with conductive material via CVD deposition of tungsten. However, in some shallow slot embodiments, conductive material is not selectively generated within the recesses, and instead, approximately 2.5 microns of conductive material is sputter deposited in the recesses at a temperature or power level that will encourage flowing of the metal into the slots. The deposited material (metal 1A) comprises aluminum, aluminum/silicon, or aluminum/silicon/copper. This results in the metal avalanching, or breaking, at the slot edges and remaining on the surface and in the bottom of the slots as shown in FIG. 5, which illustrates a cross-section of slot 400. Oxide layer(s) 410 are deposited or grown on substrate 430 and patterned. Additionally, thin oxide 430 is grown on the sides of slot 400.

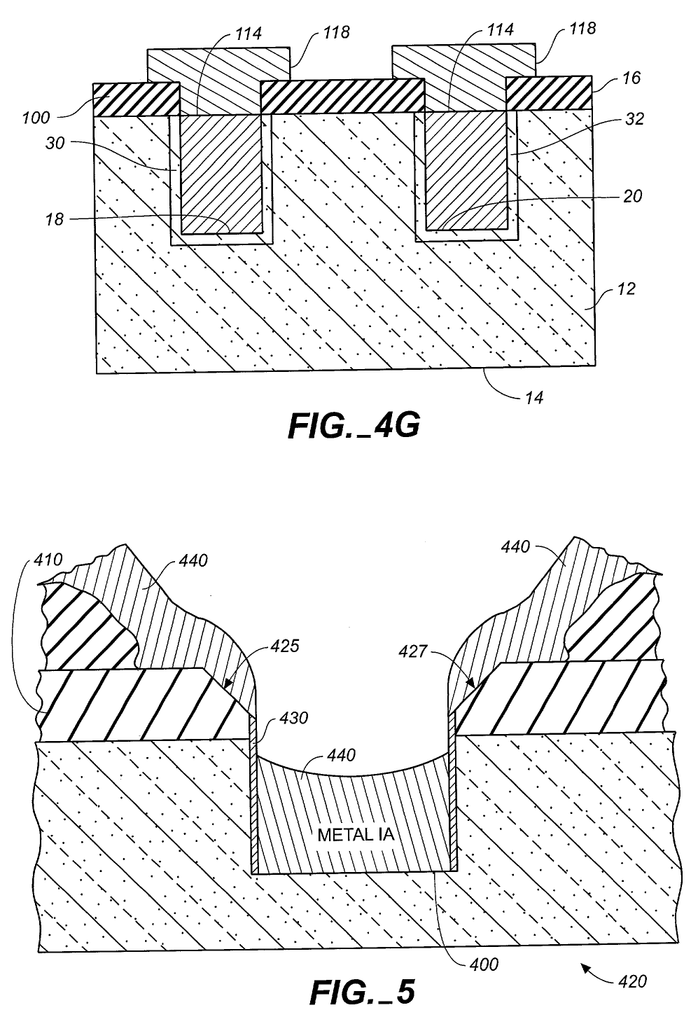

Sputtering edges of oxide layer 410 yields angled corners 425 and 427, that aid in the subsequent ‘avalanche’ of metal layer 440. Deposition of metal layer 440 results in metal beginning to fill slot 400, and covering the field, with breaks at the top corners of slot 400, that is, the metal layer (metal 1A) is not contiguous, due in part to the angled oxide corners 425 and 427. Resist is spun on the wafers and a maskless planarizing step follows to remove the resist and the portions of metal 440 in the fields, while leaving resist 500 above slots, such as slot 400, over the metal in the slots (FIG. 6). The resist is stripped and the metal is alloyed in an annealing type of atmosphere, typically forming gas, to allow the Hydrogen to anneal out the fast surface states.

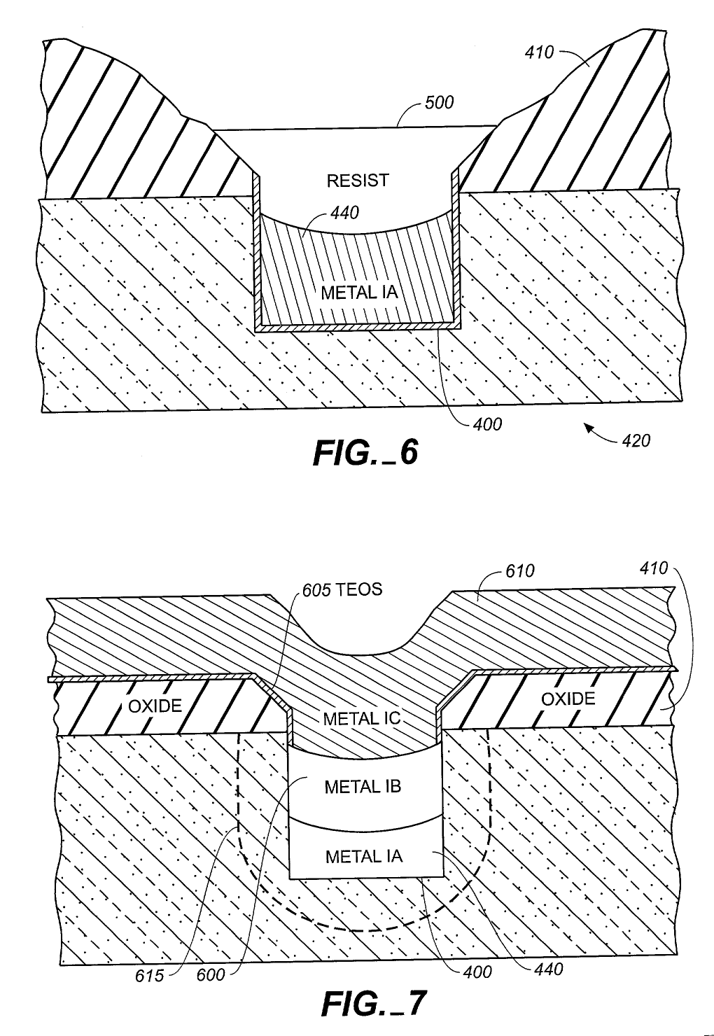

A second metal (metal 1B) 600 of approximately 2.5 microns is deposited, forming metal layer 600 (FIG. 7), with sputter etching occurring ‘in situ’ prior to the deposition to ensure good contact between the first and second deposit. This may be followed by the same maskless planarizing and resist removal and results in the slots being approximately filled with metal, with no metal in the field. The annealing step could be performed at this juncture rather than after the first metal deposition (metal 1A). Dielectric layer 605, such as a TEOS layer, is deposited and the original slot mask is used for a photomasking step that removes the dielectric formed over the slot regions. Metal is again deposited (Metal 1C), layer 605, with sputter etching in situ occurring prior to the deposition and standard metal patterning process may be used to route the metal to the proper locations. This third deposition of metal preferably is as thick as can be readily etched to form the interconnects, for example 2.5 μm. In this embodiment, the fillable recesses are relatively shallower than the embodiment described above where metal is generated within the recesses by a chemical reaction. For example, in this embodiment, recesses 6 μm deep may be provided. Boron junction 615 is shown in FIG. 7 for completeness, although it has been omitted from FIGS. 5 and 6 for ease of illustration. Although three metal depositions are described here with regard to filling slot 400 in FIG. 7, additional sequential depositions and maskless planarizations to remove the metal from the field may be performed to fill slot 400. The goal is to fill the slots and achieve a last metal layer as thick as is able to be patterned with available equipment.

Light-receiving surface 14 may be thinned, or textured, bringing the surface closer to the recesses, as shown in FIG. 2. Substrate 12 may now be subjected to oxidation at approximately 700 to 800° C. to form a thin oxide having a thickness of about 200 Å on first surface 14. This high temperature oxidation step is achievable only when tungsten rather than a low-temperature metal such as aluminum is present on substrate 12. By low-temperature metals, herein is meant metals that form a eutectic with silicon at approximately 450° C. and melt at temperatures above 600° C., e.g. aluminum. Thus, with tungsten metallization, a high-temperature oxidation may be performed that was not previously possible with other metallization schemes, such as aluminum or copper. This post-metallization oxidation step advantageously results in hydrogen gettering of the fast surface states and dangling bonds that would be in the thinned or cavity region on first surface 14, thus improving solar call efficiency. This process step also passivates the highly active light receiving surface area and maintains the integrity of the life time of the high resistance starting material, as well as the light-receiving surface.

Additional conductive material 118 may optionally be deposited using chemical vapor deposition, sputtering, evaporation, or other metallization techniques (see FIG. 4G), which metallization corresponds to metal layer 46 in FIG. 3. Particularly preferred conductive materials to deposit after the tungsten include aluminum, aluminum/silicon, aluminum/silicon/copper, or copper with aluminum being particularly preferred. This added deposition advantageously lowers the, sheet resistance of the metal that will be carrying the high solar cell current, and allows for standard bonding at the bonding pads.

An oxidation step may also be performed in the shallow slot process after the deposition of other lower-temperature metals, including aluminum. Rapid thermal processing (RTP) can be used to perform oxidation at around 450° C. if the RTP process is carried out in a wet oxygen ambient. This process is very advantageous to retain the integrity of the light receiving silicon surface. Much solar cell efficiency is lost due to surface recombination at the light receiving surface of the silicon. The deeper slot embodiment is thus advantageous in that tungsten is used in the slots and can sustain the higher temperature oxidation after this metallization, to retain the integrity of the light receiving surface of the silicon substrate.

Advantages of the presented methods include reduction of losses in the conductive material due to the reduction in the total resistance of the conduction material, improved collection of hole-electron pairs due to an increase in the depletion region volume, improved collection of hole electron pairs due to the depletion regions being closer to the light-receiving surface, and improved efficiency due to the reduced operating temperature of the solar cell.

Thus, solar cells according to the present invention have reduced IR losses (current flowing through the resistance) in the metal, primarily because the conduction material can now be thicker than is normally possible with aluminum or copper. Even though the resistivity of CVD tungsten is approximately 1.76 times that of aluminum (conventionally used as a conductive material contacting the p- and n-regions of a solar cell), the tungsten thickness is between 10 and 30 times the thickness of conventional aluminum. This results in the sheet resistance of the conductive material advantageously being reduced approximately ⅙ to 1/18 that of aluminum.

To give an example of the reduced metal losses, a standard solar cell may have a one micron thick aluminum layer having a sheet resistance of 30 milliohms per square, or a 2.5 μm thick aluminum layer having a sheet resistance of 12 milliohms per square. A typical solar cell may have metal that is ten squares long and carries a current of one amp. Therefore, a typical solar cell may have a voltage drop in the metal of between 120 millivolts to 300 millivolts.

By contrast, in a solar cell according to the present invention, tungsten fills slots in the substrate that are 6 μm wide and 20 to 60 μm deep. Therefore, the tungsten has a sheet resistance of approximately 0.8 to 2.5 milliohm per square. If aluminum is further deposited above the tungsten layer, the aluminum and tungsten in parallel may have an equivalent resistance of only 0.6 to 2.0 milliohms per square. Additionally, the current in these conductors is provided by the cells on all sides of the slots since contact is made to diffusions on all slot sides and thus current is carried in parallel. This aspect is an added advantage for supplying current for the solar cell, although more current is carried by the conductors. Thus the conductive material will carry twice the typical current density and have an equivalent sheet resistance of approximately 1.2 to 4 milliohms per square. Assuming again 10 squares of metal and a current of 1 amp, the voltage drop across the metal will be only 12 to 40 millivolts, with approximately twice the current.

This reduction in resistive-voltage loss across the metal directly influences the efficiency of a solar cell. The open circuit voltage of a typical silicon solar cell is 0.6 volts (V_{O}). If the voltage drop across the metal, as in a typical solar cell, is 150 to 300 millivolts, the resultant output power drop and resultant efficiency drop is between about 25 to 50 percent. By contrast, in the present invention, the drop in efficiency is approximately 2 to 6 percent for this particular example, or approximately one tenth the loss of prior art solar cells.

In general, widening the recesses will further lower the metal sheet resistance and thus improve the efficiency. However, widening the recesses will reduce the solar cell density, since wider slots occupy space that could be used for additional junctions to pick up the hole-electron pairs. Therefore, there is a preferred recess width, where the cell density and metal sheet resistance are optimized as to overall efficiency for a given p-type or n-type junction depth. A slot width of 6 microns, described above, is only a representative width and is not intended to limit the invention.

Additionally, the present invention provides improved collection of hole-electron pairs due to an increase in depletion region volume for the same square surface area exposed to incoming light. According to the present invention, p-type or n-type regions are provided along the periphery of the recesses. Therefore, for a recess width of 6 μm and depth of 25 μm, a depletion region having a periphery on one side of 56 μm is provided. A typical prior art solar cell having a p-type or n-type region in a planar configuration, would have a one-side periphery of only 6 μm. Therefore a standard approach would result in a surface area of 6 μm×6 μm or 36 μm² and the resultant volume of depletion region. By contrast, using the present invention, the same area exposed to light in this deep recess approach there would be 9.33 time the depletion volume. Thus, about 9.33 times the depletion region volume is provided to collect hole-electron carriers for a given light-receiving surface area with a cross-section width of 6 μm; the length is the same in both cases. This results in an increase in current output from the solar cell for a given light exposure. If, instead of 25 μm slot depth, 60 μm slots are used, the volume of the depletion region would increase by a factor of 2.4 and result in 22.4 times the depletion volume provided by prior art solar cells exposed to the same unit of surface area. All these features contribute to enhanced efficiency of solar cells according to the present invention.

Further, the present invention provides for improved collection of hole electron pairs as the depletion regions are closer to the light-receiving surface. As noted, hole-electron pairs are generated at the light-receiving surface of the solar cell. These carriers must travel to the depletion regions of the p- or n-type regions without recombining in the substrate. Generally, the distance carriers may travel before recombining is characterized by the carrier diffusion length. In a typical prior art high lifetime silicon solar cell, this carrier diffusion length is approximately 150 μm. In a typical solar cell, p- and N-type regions are approximately 3-5 μm deep, and the associated depletion region may extended another 5-10 μm into the substrate. Accordingly, the edge of the depletion region in a typical solar cell is 8-15 μm away from the second surface. The distance between the edge of the depletion region and the light-receiving surface depends on the thinning of the substrate. Generally, the light-receiving surface will be approximately 150 μm away from the opposite surface (second surface). That is, the thinned substrate will be approximately 150 μm thick. The thinned substrate thickness is governed by the thinning technique employed. Therefore, in a typical prior art solar cell, the edge of the depletion region is about 135-142 μm (150 microns less the 8-15 μm of depth of the depletion regions) away from the light receiving surface. Therefore the carrier diffusion length (maximum) is just able to reach the depletion region and many of them will be lost due to recombination on their way to the depletion region.

By contrast, solar cells according to the present invention include a recess that may extend up to 60 μm into the second substrate surface, and generally between 25-60 μm. Accordingly, the edge of the depletion region may be approximately 90-120 μm away from the light receiving surface. This shortened distance improves the percentage of hole-electron pairs that reach the depletion region without recombining, thereby improving the efficiency of the solar cell.

The present invention further enhances solar cell efficiency in that tungsten allows a fairly high temperature oxidation after the tungsten metal step. This results in returning the light receiving surface to a high integrity surface, and reduces surface recombination. Withdrawal of the material from the furnace after this oxidation process step in a nitrogen atmosphere results in low fixed surface states.

The present invention further provides an improvement in efficiency due to improved thermal management. The efficiency of a solar cell drops as the temperature of the device rises. A temperature increase may be due to heat generated by light hitting the cell or by power dissipation within the cell. A prior art silicon solar cell typically cannot provide useful power at a temperature above 200° C. Heat is typically carried off by heat sinks, heat conduction through the metal contacts and out through leads or convection. But according to the present invention, the conductive material forms many fingers into the substrate recesses at a depth of, for example, 25 to 60 μm. These metal fingers contact the silicon directly. Therefore heat transfer is improved significantly from the metal fingers to the silicon and out via conduction. Heat transfer through silicon is ten times better than through oxide and 200 times better than convection to air. Since much of the slot regions directly contact the silicon, the heat transfer is substantially improved over the prior art constructions in which only surface contact exists and the heat must be dissipated by air or must make contact to heat sinks. Further, in the present invention, the conductive fingers act as heat sinks that carry heat generated through the substrate to air, and also reach the bonding pads. This increase in the thickness of the bonding pads provides a type of heat sink whereby the transfer of heat from the bonding pads to the assembly wires (bond wires) is substantially improved. These attributes allow a solar cell according to the present invention to operate cooler at a given condition, resulting in higher efficiencies.

As can be seen from the foregoing, an efficient solar cell has been provided having a plurality of deep recesses in a substrate surface. Conductive material, preferably tungsten, is disposed within the recesses (slots). Overall, solar cells according to the present invention have improved efficiencies that may attain 50 to 75 percent when measured by methods used on typical solar cells that have 15 to 25 percent efficiencies.

An efficient solar cell has been provided in a second embodiment where shallower recesses are formed in a substrate surface, with Aluminum, Aluminum/Silicon, Aluminum/Silicon/Copper, and Copper conductive material to improve the efficiency to approximately 35 percent when measured by methods used on typical solar cells that have 15 to 25 percent efficiencies.

The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the claims appended hereto and their equivalents.

What is claimed is:

1. A solar cell comprising a substrate having a light-receiving first surface and a variegated second surface, the second surface defining a first recess, the substrate being doped within the first recess to provide a first doped region defining the first recess and at least one conductive material disposed in each of the first recesses for permitting electrical connections to the doped region.

2. A solar cell according to claim 1, wherein said conductive material comprises tungsten.

3. A solar cell according to claim 1, wherein said second surface further defines a second recess, the substrate being doped within the second recess to provide a second doped region, and wherein said first doped region is a p-type region and said second doped region is an n-type region.

4. The solar cell of claim 3 wherein the substrate is doped with boron within the first recess to provide a p-type region defining the first recess.

5. The solar cell of claim 3 wherein the substrate is doped with and element chosen from the group consisting of Phosphorous and Arsenic within the second recess to provide a n-type region defining the second recess.

6. The solar cell of claim 3 wherein said first and second recesses comprise first and second slots.

7. The solar cell of claim 3, wherein said first and second slots are provided simultaneously.

8. The solar cell of claim 3 wherein the second surface defines a plurality of first recesses and a plurality of second recesses.

9. The solar cell of claim 8, wherein said plurality of first and second recess are all provided in one step.

10. The solar cell of claim 3 wherein the first and second recesses extend parallel to each other.

11. The solar cell of claim 3, wherein said at least one conductive material includes tungsten.

12. The solar cell of claim 3, wherein said at least one conductive material includes tungsten and aluminum.

13. The solar cell of claim 3, wherein tungsten completely fills at least one of said slots.

14. The solar cell of claim 3, further comprising
a first bonding pad electrically connected to said at least one conductive material disposed in said p-type recess; and
a second bonding pad electrically connected to said at least one conductive material disposed in said n-type recess.

15. The solar cell of claim 6, wherein each of said slots ranges from 25 to 60 microns in length and 5 to 20 microns in width.

16. The solar cell of claim 3, wherein said substrate comprises silicon.

17. A method for forming a solar cell from a substrate having a first light-receiving surface and an opposite second surface, comprising the steps of:
(a) forming a first and second recess extending through the second surface;
(b) providing a p-type region defining the first recess;
(c) providing a n-type region defining the second recess; and
(d) selectively providing at least one conductive material in said recesses by chemical reaction.

18. The method of claim 17, wherein the p-type region defining the first recess comprises Boron doped silicon.

19. The method of claim 17, wherein the n-type region defining the second recess comprises silicon doped with an element chosen from the group consisting of Phosphorous and Arsenic.

20. The method of claim 17, wherein said first and second recess are formed as first and second slots.

21. The method of claim 20, wherein said first and second slots are formed in one step.

22. The method of claim 17, wherein a plurality of first recess and a plurality of second recesses are formed.

23. The method of claim 22, wherein said plurality of first and second recesses are all provided in one step.

24. The method of claim 17, further comprising the step of depositing a second conductive material in said recesses.

25. The method of claim 17, wherein said first conductive material is tungsten.

26. The method of claim 24, wherein said first conductive material is tungsten and said second conductive material is aluminum.

27. The method of claim 17, further comprising the step of:
oxidizing said substrate at a temperature greater than approximately 450 degrees Celsius after said metallization step.

28. The method of claim 20 wherein said selectively depositing step includes the step of generating tungsten on a silicon substrate by means of chemical reaction followed by thickening the tungsten by vapor deposition.

29. The method of claim 28 wherein said depositing tungsten comprises providing a patterned masking layer on said second substrate surface and introducing WF6 gas to said substrate such that tungsten is selectively deposited in said first and second recesses.

30. The method of claim 28 wherein said selectively depositing step further comprises thickening said tungsten by reacting hydrogen gas with said WF6.

31. The method of claim 17, wherein said substrate is silicon and wherein providing said p-type region comprises:
oxidizing said substrate such that silicon dioxide is formed along the surface of said recess;
patterning said silicon dioxide to expose said p-type recess;
exposing said substrate to boron in an oxidizing atmosphere.

32. The method of claim 30, wherein providing said n-type region comprises:
patterning said silicon dioxide to expose said n-type slots;
exposing said substrate to a dopant chosen from the group consisting of Phosphorous and Arsenic.

33. The method of claim 17, further comprising the step of
performing a rapid thermal processing oxidation at about 450 degrees Celsius.

34. A method for forming a solar cell from a substrate having a first light-receiving surface and an opposite second surface, comprising the steps of:
(a) forming a first and second recess extending through the second surface;
(b) providing a p-type region defining the first recess;
(c) providing a n-type region defining the second recess; and
(d) depositing a conductive material in said recess under conditions sufficient for the material to flow into the recesses.

35. The method of claim 33 further comprising:
(e) planarizing said substrate such that conductive material remains in said recesses.

36. The method of claim 34 further comprising:
depositing a second layer of conductive material in said recesses.
